(19) United States
(12) Patent Application Publication
(10) Pub. No.: US 2007/0155071 A1
(43) Pub. Date: Jul. 5, 2007

(54) Method of reducing edge height at the overlap of a layer deposited on a stepped substrate

(76) Inventors: Winston Kong Chan, Princeton, NJ (US); Alfred Joseph Ulmer, Beverly, NJ (US)

Correspondence Address: REED SMITH LLP, 2500 ONE LIBERTY PLACE, 1650 MARKET STREET, PHILADELPHIA, PA, 19103, US

(21) Appl. No.: 11/545,078

(22) Filed: Oct. 6, 2006

Related U.S. Application Data
(60) Provisional application No. 60/724,535, filed on Oct. 7, 2005.

(51) Int. Cl. H01L 21/84; H01L 21/00

(52) U.S. Cl. 438/158

(57) ABSTRACT

A system and method for preparing a stepped substrate and an apparatus are disclosed. The method comprises depositing photoresist on a stepped substrate, removing a first portion of the photoresist, reflowing the remaining portion of the photoresist; and etching a portion of the reflowed remaining photoresist and a portion of the stepped substrate. The apparatus comprises a deposited photoresist layer on a stepped substrate, wherein a portion of the photoresist is removed, a reflowed portion of the remaining photoresist, an etched portion of the reflowed photoresist, and an etched portion of the stepped substrate. The system for preparing a stepped substrate comprises a first processing tool for depositing at a portion of photoresist on the stepped substrate, a second processing tool for removing at least a first portion of the photoresist, a third processing tool for reflowing at least a portion of the remaining portion of the photoresist, and a fourth processing tool for etching a portion of the reflowed photoresist and a portion of the stepped substrate.

### CROSS REFERENCE TO RELATED APPLICATIONS

This Application claims the benefit of priority to copending U.S. Provisional Patent Application Ser. No. 60/724,535, entitled “Method Of Reducing The Step Height At The Overlap Of A Layer Deposited On A Stepped Substrate”, filed Oct. 7, 2005, the entire disclosure of which is hereby incorporated by reference as if being set forth herein in its entirety.

### STATEMENT REGARDING FEDERALLY SPONSORED RESEARCH

### BACKGROUND OF THE INVENTION

1. Field of the Invention

The present invention is directed generally to a method for precision processing for semiconductor structures, and for precision processing of metals deposited on substrates, for use in complementary metal oxide semiconductors (CMOSs) and CMOS structures.

2. Description of the Background

Silicon (Si) is the most widely used semiconductor material in modern electronic devices. Single crystalline Si of high quality is readily available, and the processing and microfabrication of Si are well known. The transparency of Si in the near-infrared makes Si an ideal optical material.

In part due to these ideal optical properties, Si-based waveguides are often employed as optical interconnects on Si integrated circuits, or to distribute optical clock signals on a Si-based microprocessor. A waveguide is a conductor or directional transmitter for electromagnetic waves. In these and other instances, Si provides improved integration with existing electronics and circuits. However, at present pure Si optical waveguide technology is not well developed, in part because fabrication of waveguides in Si requires a core with a higher refractive index than that of crystalline Si (c-Si).

Amorphous silicon (a-Si) presents advantageous properties as a Si-based waveguide core material. A-Si is a non-crystalline allotropic form of silicon. Silicon is normally tetrahedrally bonded to four neighboring silicon atoms, which is the case in amorphous silicon. However, unlike c-Si, a-Si does not form a continuous crystalline lattice. As such, some atoms in an a-Si structure may have “dangling bonds,” which occur when one of the tetrahedral bonds of the a-Si does not bond to one of the four neighboring atoms. Thus, a-Si is “under-coordinated.” The under-coordination of a-Si may be passivated by introducing hydrogen into the silicon. The introduction of hydrogen for passivation forms hydrogenated a-Si. Hydrogenated a-Si provides high electrical quality and relatively low optical absorption.

Historically, optical links were single wavelength and point-to-point, with all functionality in the electronics domain. The implementation of telecommunication functions in the optical domain, in conjunction with the aforementioned development of the understanding of silicon as an optical material, led to the development of the optoelectronic integrated circuit. An opto-electronic integrated circuit (OEIC) device combines optics with electronics in an integrated form. OEIC technology, which employs waveguides, is commonly used, for example, in optical fiber communication devices and methods. A typical OEIC includes conventional integrated circuit components as well as optical components. Conventional integrated circuit components include for example, transistors, diodes, resistors, and electrically conductive interconnects. Examples of optical components include light receiving devices such as photodiodes, light emitting devices (such as light emitting diodes (LED)), optical reflectors (such as metallic mirrors), optical filters, and waveguides. The OEIC fabrication process borrows heavily from the electronic integrated circuit field, and as such, may employ planar deposition, photolithography, dry etching, and multi-layer substrates to form optical waveguides analogous to electronic circuit conductors. Typical OEIC waveguides are optical interconnects that provide an optical path between optical and/or opto-electronic components.

The design of integrated circuits (ICs), and particularly OEICs, has been largely driven by the need to increase the density of features to provide the aforementioned multi-layer substrates. Density may be increased by reducing feature size, and/or by increasing the vertical complexity of chip structure by the addition of more layers. Vertical structuring of ICs has been advanced by the introduction of double-level metal interconnects in bipolar technology. However, while a double-level metal process may be successfully implemented for bi-polar ICs, complementary metal oxide semiconductors (CMOSs) vertical structuring development necessitated partial planarization of the interlayer dielectric (ILD) by thick depositions. To enable three or more metal level processes in CMOS architecture, a more global planarization is required to remove the uneven surfaces of the ILD.

Chemical mechanical polishing (CMP) was introduced to provide a more global planarization. CMP uses both active chemicals and particles, in a slurry, along with motion, to uniformly reduce the amount of material on a surface to be planarized. However, in silicon processes wherein features are both dense and isolated on the same chip, or in applications wherein OEIC precision is required, planarization using standard CMP may be less than desirable. Although CMP has the ability to planarize layers to with a few nanometers, CMP to date is not particularly suitable for planarizing softer materials or more precise surfaces, due in part to a lack of process refinement that precludes an obtaining of both local and global planarization simultaneously.

Therefore, the need exists for a method to locally and globally planarizing ILDs, including a-Si. Such a method and apparatus would, preferably, allow for more controlled etching and eroding, and for other forms of precision processing of soft metal layers and depositions, which would, in turn, allow for the making of CMOS structures and OEICs with greater complexity.

### BRIEF SUMMARY OF THE INVENTION

The present invention is directed to CMOS and OEICs and their creation and, more specifically, precision processing of multi-layered substrates. One aspect of the present invention is a means of achieving a beneficial reduction in step height of a stepped substrate which planarizes the substrate, wherein the stepped substrate may have a multi-layered structure. Such method or means comprises depositing photoresist on a stepped metal substrate removing at least some of the photoresist, reflowing at least some of the photoresist, and etching at least some of the remaining photoresist and at least some of the metal substrate. The reflowing step in this method specifically comprises the step of heating the substrate at 125° C. for five minutes after photolithographically exposing and developing the substrate. In such method, the thickness of photoresist at the step may be about 3 micrometers thick prior to reflowing and, subsequent to reflowing, the photoresist thickness may be reduced to about 2.5 micrometers. Such method may also comprise the steps of descumming, carbon tetraflouride plasma etching at least some of the remaining photoresist and at least some of the metal substrate, and oxygen plasma etching at least some of the remaining photoresist.

The present invention meets the needs evidenced in the prior art by providing a method of more globally reducing the step heights of multi-layered substrates and thereby providing a means of enabling CMOSs to have greater complexity in their architecture.

### BRIEF DESCRIPTION OF THE SEVERAL VIEWS OF THE DRAWINGS

For the present invention to be clearly understood and readily practiced, the present invention will be described in conjunction with the following figures, wherein like reference numerals represent like elements, and wherein:

FIG. 1 illustrates a method of preparing a substrate for precision processing, according to an aspect of the present invention;

FIG. 2 illustrates a method of etching a substrate to be suitable for semiconductor use, according to an aspect of the present invention;

FIG. 3 illustrates a substrate suitable for semiconductor use, according to an aspect of the present invention;

### DETAILED DESCRIPTION OF THE INVENTION

It is to be understood that the figures and descriptions of the present invention have been simplified to illustrate elements that are relevant for a clear understanding of the present invention, while eliminating, for the purpose of clarity, many other elements found in typical semiconductor fabrication apparatuses, methods, and systems. Those of ordinary skill in the art may recognize that other elements and/or steps are desirable and/or required in implementing the present invention. However, because such elements and steps are well known in the art, and because they do not facilitate a better understanding of the present invention, a discussion of such elements and steps is not provided herein. The disclosure herein is directed to all such variations and modifications to such elements and methods known to those skilled in the art.

Generally, the present invention provides a system, apparatus, and method for etching a metal layer deposited on a stepped substrate, in which the etched metal layer overlaps the step of the stepped substrate, and wherein the thickness of the portion of the metal layer on top of the step is reduced.

The present invention further provides a system, apparatus, and method for controlled etching, eroding, and precision processing of soft metal layers and depositions, which enables the creation of CMOS, OEIC, and CMOS structures with greater complexity.

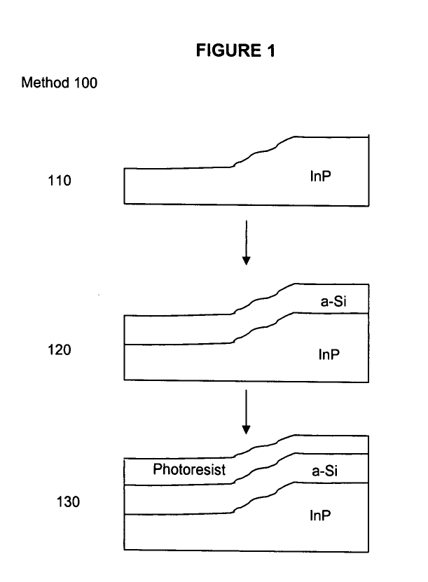

Referring now to FIG. 1, there is shown method and system (hereinafter method) 100 according to an aspect of the present invention. Method 100 may include stage 110, in which a stepped substrate (or a substrate with at least one mesa) is prepared. Areas of a substrate with mesas may be, generally, “active” areas, as described herein, and off-mesa areas (or non-stepped areas) may, generally, be “passive” areas. The substrate, which may be an indium phosphide (InP) substrate or other substrate type known to one skilled in the art to be operable in the present invention, may be prepared by etching to form a stepped substrate, such as to form a laser waveguide structure, or may be prepared from a patterned film or by any other means as would be apparent to one with ordinary skill in the art for substrate preparation.

In stage 120, after the stepped substrate is prepared, a layer of metal is deposited on the stepped substrate to form a multi-layered structure. This deposition may be by any means known to one with ordinary skill in the art. The deposited material may be amorphous silicon (a-Si), which may form up a waveguide structure having, for example, a 3 micrometer thickness, or this or any other thickness, to allow subsequent precision processing. The a-Si may be uniformly deposited over the entire stepped substrate surface, as would be apparent to one with ordinary skill in the art.

In stage 130, photoresist may be deposited on the multi-layer substrate prepared in step 120. The photoresist may serve as a mask to protect the a-Si layer in the off-mesa (or passive) areas during etching over the mesa areas. Photoresist may be any suitable photoresist material as known to one of ordinary skill in the art for use to protect an a-Si layer during the etching process, and may preferably be, but is not be limited to, AZ5214 and AZ1529. The photoresist may be deposited on the multi-layer substrate through spin coating, which normally leaves the photoresist thinner near the mesa (or step) areas due to the dynamics of the spin coating process. In an exemplary embodiment, photoresist AZ5214 may spin coated on the substrate at a speed of 3,500 rpm to create, for example, a 3.1 micrometer thick layer of photoresist on the multi-layered substrate. Any thickness to cover the a-Si in the passive areas may, of course, be employed.

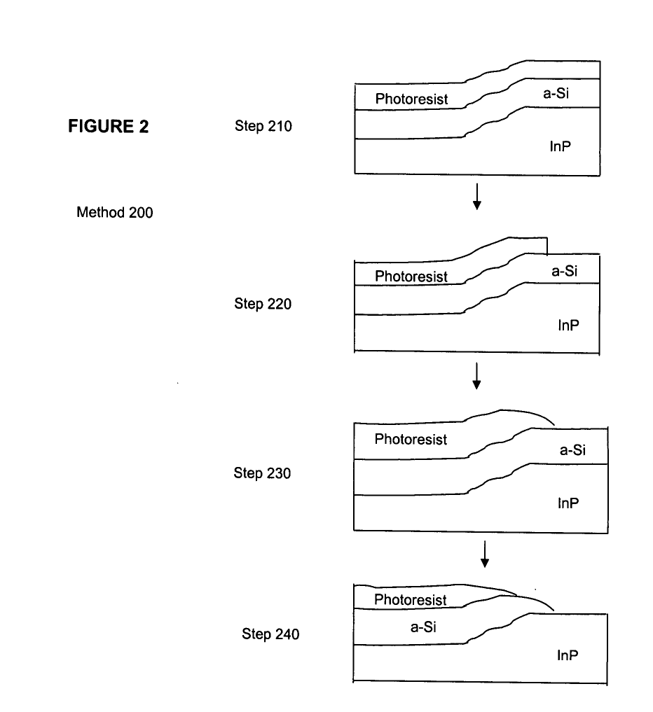

Referring now to FIG. 2, there is shown method 200 according to an aspect of the present invention. In stage 210, the multi-layered substrate created in stage 130, which may have thereon InP, a-Si, and photoresist, sequentially, may be baked on a hotplate, for example, at 90° C. for two (2) minutes. In stage 220, the multi-layered substrate may be etched photolithographically by exposure and development, such as, for example, by using a four 4 to 1 solution of water to developer in a conventional manner. The developer may be a multi-stage developer, or any developer, known to those of ordinary skill in the art, such as, but may not be limited to, AZ400K.

Photolithographically etching a multi-layered may typically involve exposing the photoresist to a patterned beam of radiation. The patterned beam of radiation may selectively expose the photoresist over regions of the multi-layered substrate, while leaving the photoresist over other regions not exposed. The photoresist utilized for forming a mask may be a positive photoresist or negative photoresist.

The result of the exposure and development may leave the multi-layered substrate of stage 210 with some areas void of photoresist, and such areas may include exposed a-Si. In stage 230, the multi-layered substrate may be subjected to a reflow process, wherein the multi-layered substrate may be heated, such as with a hotplate at 125° C. for five (5) minutes. In this stage, the photoresist may reflow and thin from certain areas still having photoresist thereon, such as, for example, on the edges of the previous etch. According to an aspect of the present invention, the previous stage's etching may be near the edges of the aforementioned mesas. This may leave a ledge of photoresist at that point and, after reflowing the photoresist, the photoresist may be thinned to a round at the edge of the mesa. The photoresist may be, for example, reduced in thickness to about 2.5 micrometers at the round from a pre-reflow thickness of about 3 micrometers. It is this reflow that, after final etching and processing, allows the a-Si in the active areas to be well exposed as desired, and to be exposed on different surfaces, while the a-Si in the passive areas continues to be protected.

In stage 240, the photoresist thickness may be uniformly reduced over the entire multi-layered substrate, such as by way of an oxygen (02) plasma etch, which may also allow the thickness of the photoresist at the top of the mesa to be reduced further. In addition, at stage 240, preferably the multi-layered substrate may be subjected to a two (2) minute O₂ descum process at 125 W of power, as is known to those of ordinary skill in the art. Finally, the a-Si in the active areas may be plasma etched, preferably with carbon tetraflouride (CF₄) plasma at 100 W of power and 50 mT of pressure for forty (40) minutes, thereby uniformly etching the entire multi-layered substrate surface. The photoresist may be further removed using a two (2) minute O₂ plasma etch at 125 W of power, an acetone rinse, and a second O₂ plasma etch at 275 W of power for thirty (30) minutes.

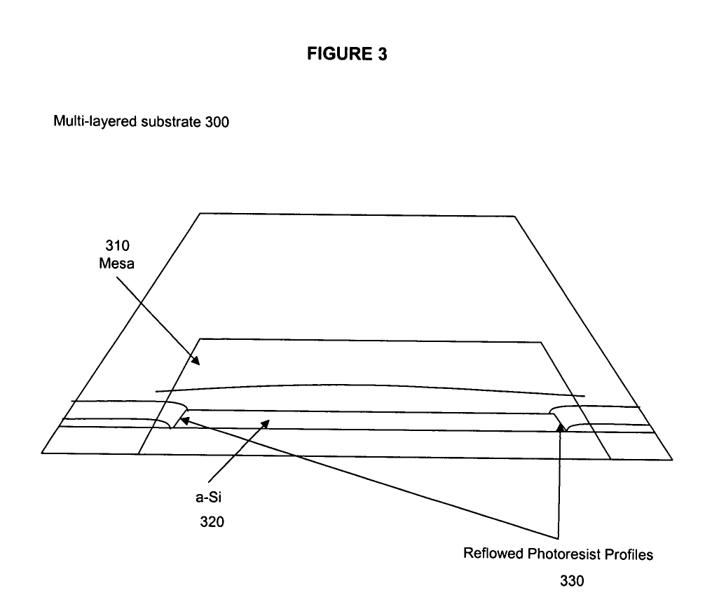

Referring now to FIG. 3, there is shown multi-layered substrate 300 according to an aspect of the present invention. Multi-layered substrate 300 may be prepared via method 100 and/or method 200 to stage 230. Multi-layered substrate 300 is the result of reflowing photoresist before final plasma etching of the photoresist and a-Si. In multi-layered substrate 300, the a-Si 320 may be visible from underneath the photoresist layer. The reflowed photoresist profiles 330 may cover the a-Si 320 layer, and as shown, curve down to the a-Si layer without forming right-angle edges with the a-Si layer. According to an aspect of the present invention, it is these curved and reduced-thickness profiles of photoresist ending at the a-Si layer which may allow for more complex CMOSs and structures to be made. The reflow of photoresist leads to reduced-thickness profiles. The reflow and reduced-thickness profiles may be verified using measurement techniques known to those of ordinary skill in the art.

During fabrication processing steps may be performed while maintaining the multi-layered substrate in a vacuum environment. For example, in a sequence of plasma etching, it may be desirable to maintain the multi-layered substrate in a vacuum environment in order to minimize, or avoid if possible, physical and/or chemical changes in the etched surface. Further, keeping the multi-layered substrate in a vacuum environment minimizes particle contamination of the etched surfaces.

A cluster tool, or any other processing tool as is known to persons of ordinary skill in the art, may be utilized to execute a number of sequential processing steps, such as etching and physical vapor deposition, in fabricating chambers, reactors, or tools that share a common environment, such as a vacuum, and the cluster tool provides transport for the structure between the fabricating chambers while maintaining the structure in the common environment. It is well known to persons of ordinary skill in the art that certain tools, including but not limited to a cluster tool, may provide a process module wherein all of the components of a particular processing step are integrated using robotics, and wherein automatic logging of structures can be provided.

Certain processing steps of the present invention may be executed using at least one tool. Such a tool may include, for example, process or fabricating chambers, a transfer chamber, a preclean chamber, a buffer chamber, a wafer orienter/degas chamber, a cooldown chamber, and a pair of loadlock chambers. To effectuate structure transfer between these chambers, chambers may contain a robotic transfer mechanism. The robotic transport mechanism may transport the structures from cassettes to any necessary chambers. Structures may be typically transferred from storage to the system in transport cassettes. Individual structures may be carried on a transport blade located at the end of a first robotic mechanism. The transport operation may be controlled by a sequencer.

The transfer chamber may have access to a series of process chambers, as well as a preclean chamber and a cooldown chamber. To effectuate transport of a structure amongst the chambers, the transfer chamber may contain a second robotic transport mechanism. The second robotic transport mechanism may have a transport blade attached to its distal end for transporting individual structures. In operation, the transport blade of the second transport mechanism may retrieve an structure from the preclean chamber and transfer that structure to the first stage of processing, such as, for example, an etching chamber. Once the structure has been processed in the etching chamber, the structure may be transported to, for example, the next chamber, and so on. Following completion of processing within the process chambers, the transport mechanism may move the structure from the process chamber and transport the structure to a cooldown chamber. The structure may then be removed from the cooldown chamber using the first transport mechanism within the buffer chamber. Lastly, the processed structure may be placed in a transport cassette within a loadlock chamber, for example.

Tools, as such just described and, including, but not limited to, cluster tools, may be employed to execute processing steps of the novel techniques for fabricating waveguide structures of the present invention. A first structure may be fabricated, such that the structure provides a stack including a substrate layer, upon which is deposited a bottom layer (such as InP), followed by a layer of a-Si, upon which photoresist is placed. Another tool may then be employed such that a vacuum environment is maintained during each of the transfers of the structure inside the cluster tool.

The fabrication techniques of the present invention for forming waveguide structures may further employ a particular sequence of processing steps. Each processing step may be performed at a fabrication station. All or some of the fabrication stations and their respective processing steps may be integrated by means of a novel apparatus including a controller. The controller may be adapted for controlling a number of fabrication stations that are utilized in the formation of fabricated structures, such as the structures described above. A novel manufacturing system for fabricating structures may include a controller and a plurality of fabrication stations. Additionally, this manufacturing system may have operative links that provide connections between the controller and the fabrication stations, respectively. The novel apparatus may include a data structure, such as a computer program, that causes the controller to control the processing steps at each of the fabrication stations and to, optionally, regulate the sequence in which fabrication stations are used in order to form the novel structures.

Examples of suitable controllers may include conventional computers and computer systems, including one or more computers that are operably connected to other computers or to a network of computers or data processing devices. Suitable computers may include computers commonly known as personal computers. The data structure that may be used by the controller may be stored on a removable electronic data storage medium, such as computer floppy disks, removable computer hard disks, magnetic tapes, compact disks, and/or optical disks, to facilitate the use of the same data structure at different manufacturing locations. Alternatively, the data structure may be stored on a non-removable electronic data storage medium, such as a medium positioned at a location that may be remote from the controller, using such data storage devices as are well known to those of ordinary skill in the art. The data structure may be communicated from a remote location to the controller using communicating techniques which are well know to those of ordinary skill in the art, including hard wire connections, wireless connections, and data communication methods utilizing one or more modems or techniques using one or more computers commonly known as servers. The data storage medium may be operably connected to the controller using methods and device components which are well known to those of ordinary skill in the art.

Additional fabrication stations may be added to the above-described manufacturing system. For example, one or more planarizing stations may be added. Further, the invention may be equally operable in systems wherein a controller may cause the sequence to be altered, for example by repeating a previously executed processing step if test results indicate that this processing step should be partly or completely repeated. Alternatively, the process sequence (which may be controlled by the aforementioned controller) may include processing steps, such as surface preparation, which may be performed following any of the fabrication stations. It may also be contemplated that one or more fabrication stations may be positioned at a location that may be remote from the other fabrication stations, in which case an additional controller or a network of controllers may be employed to control the remotely located manufacturing station.

Those of ordinary skill in the art will recognize that many modifications and variations of the present invention may be implemented. The foregoing description and the following claims are intended to cover all such modifications and variations falling within the scope of the following claims, and the equivalents thereof.

What is claimed is:

1. A method for preparing a stepped substrate, comprising:
depositing photoresist on a stepped substrate;
removing at least a first portion of the photoresist;
reflowing the remaining portion of the photoresist; and
etching at least a portion of the reflowed remaining photoresist and at least a portion of the stepped substrate.

2. The method of claim 1, wherein the stepped substrate comprises amorphous silicon.

3. The method of claim 1, wherein the stepped substrate is multi-layered and a first upper layer of the multi-layers is amorphous silicon and a second lower layer is indium phosphide.

4. The method of claim 1, wherein the photoresist is about 3 micrometers thick.

5. The method of claim 1, wherein said removing at least a first portion of the photoresist comprises photolithographically etching the first portion of the photoresist.

6. The method of claim 1, wherein said etching at least a portion of the remaining photoresist comprises plasma etching.

7. The method of claim 1, wherein said etching at least a portion of the remaining photoresist and at least a portion of the stepped substrate comprises: descumming;
carbon tetraflouride plasma etching the at least the portion of the remaining photoresist and the at least the portion of the stepped substrate; and
oxygen plasma etching the at least the portion of the remaining photoresist.

8. The method of claim 1, wherein said reflowing reduces the remaining portion of the photoresist from about 3 micrometers thick to about 2.5 micrometers thick.

9. The method of claim 1, wherein said reflowing comprises heating the stepped substrate at 125° C. for five minutes.

10. An apparatus, comprising:
a deposited photoresist layer on a stepped substrate, wherein at least a portion of the photoresist is removed;
at least a reflowed portion of the remaining photoresist;
at least an etched portion of the reflowed photoresist; and
at least an etched portion of the stepped substrate.

11. The apparatus of claim 10, wherein said stepped substrate comprises amorphous silicon.

12. The apparatus of claim 10, wherein said stepped substrate is multi-layered and a first upper layer of the multi-layers is amorphous silicon and a second lower layer is indium phosphide.

13. The apparatus of claim 10, wherein said deposited photoresist layer is about 3 micrometers thick.

14. The apparatus of claim 10, wherein at least a portion of said at least a reflowed portion of the remaining photoresist is about 3 micrometers to about 2.5 micrometers thick.

15. An system for preparing a stepped substrate, comprising:
a first processing tool for depositing at least a portion of photoresist on the stepped substrate;
a second processing tool for removing at least a first portion of the photoresist;
a third processing tool for reflowing at least a portion of the remaining portion of the photoresist; and
a fourth processing tool for etching at least a portion of the reflowed photoresist and at least a portion of the stepped substrate.

16. The system of claim 15, wherein said first processing tool deposits the photoresist on an amorphous silicon stepped substrate.

17. The system of claim 15, wherein said first processing tool deposits photoresist on a stepped substrate having a first upper layer of amorphous silicon and a second lower layer of indium phosphide.

18. The system of claim 15, wherein said first processing tool deposits a layer of about 3 micrometers thickness of photoresist on the stepped substrate.

19. The system of claim 15, wherein said second processing tool further comprises a photolithographical processing tool capable of photolithographically etching said portion of photoresist.

20. The system of claim 15, wherein said third processing tool further comprises a plasma etching processing tool capable of plasma etching said portion of the remaining photoresist.

21. The system of claim 15, wherein said fourth processing tool further comprises:
a descumming processing tool;
a carbon tetraflouride plasma etching processing tool capable of plasma etching said remaining photoresist portion and at least the portion of the stepped substrate; and
an oxygen plasma etching processing tool capable of oxygen plasma etching said remaining photoresist portion.

22. The system of claim 15, wherein said plasma etching processing tool is capable of reducing said portion of the remaining photoresist from about 3 micrometers thick to about 2.5 micrometers thick.

23. The system of claim 15, wherein said third processing tool further comprises a heating processing tool capable of heating the stepped substrate at 125° C. for five minutes.
